(19) United States
(12) Patent Application Publication
(10) Pub. No.: US 2026/0190509 A1
(43) Pub. Date: Jul. 2, 2026

(54) METHOD FOR MANUFACTURING SEMICONDUCTOR DEVICE

(71) Applicant: CANON KABUSHIKI KAISHA, Tokyo (JP)

(72) Inventors: KOJI HARA, Chiba (JP); AKIRA MATSUZAKI, Kanagawa (JP)

(21) Appl. No.: 19/425,127

(22) Filed: Dec. 18, 2025

(30) Foreign Application Priority Data
Dec. 26, 2024 (JP) 2024-230271

(51) Int. Cl. H10F 39/00

(52) U.S. Cl. CPC H10F 39/024

(57) ABSTRACT

A method for manufacturing a semiconductor device including a substrate, the substrate including a first surface, a second surface opposed to the first surface, and a plurality of semiconductor regions disposed between the first surface and the second surface, the method includes preparing the substrate having groove portions disposed between the plurality of semiconductor regions, each of the groove portions having a trench structure extending from the first surface, and forming a first film having a flat upper surface on the substrate by applying a precursor so that an amount of the precursor applied on upper parts of the groove portions is greater than an amount of the precursor applied on portions other than the upper parts of the groove portions.

### BACKGROUND

### Field of the Technology

The present disclosure relates to a method for manufacturing a semiconductor device.

### Description of the Related Art

Japanese Patent Laid-Open No. 2020-181953 describes a semiconductor device that includes isolation portions extending from a light incident surface of a semiconductor substrate.

### SUMMARY

A method of forming isolation portions described in Japanese Patent Laid-Open No. 2020-181953 includes a step of planarization by removing an insulating film provided on portions other than grooves formed using a chemical vapor deposition (CVD) method while the insulating film in the grooves remains. The planarization is affected by arrangement density of the grooves. Thus, it is difficult to easily achieve a high degree of flatness. The present disclosure is directed to providing a method for facilitating formation of isolation portions.

According to an aspect of the present disclosure, a method for manufacturing a semiconductor device including a substrate, the substrate including a first surface, a second surface opposed to the first surface, and a plurality of semiconductor regions disposed between the first surface and the second surface, the method includes preparing the substrate having groove portions disposed between the plurality of semiconductor regions, each of the groove portions having a trench structure extending from the first surface, and forming a first film having a flat upper surface on the substrate by applying a precursor so that an amount of the precursor applied on upper parts of the groove portions is greater than an amount of the precursor applied on portions other than the upper parts of the groove portions.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic diagram illustrating a configuration of a planarization apparatus.

FIGS. 2A, 2B, and 2C are schematic diagrams illustrating planarization processing.

FIGS. 3A and 3B are schematic diagrams illustrating a method for manufacturing a semiconductor device according to a first embodiment.

FIGS. 4A, 4B, and 4C are schematic diagrams illustrating the method for manufacturing the semiconductor device according to the first embodiment.

FIGS. 5A and 5B are schematic diagrams illustrating the method for manufacturing the semiconductor device according to the first embodiment.

FIGS. 6A and 6B are schematic diagrams illustrating the method for manufacturing the semiconductor device according to the first embodiment.

FIGS. 7A and 7B are schematic diagrams illustrating a method for manufacturing a semiconductor device according to a second embodiment.

FIGS. 8A, 8B, and 8C are schematic diagrams illustrating the method for manufacturing the semiconductor device according to the second embodiment.

FIGS. 9A, 9B, and 9C are schematic diagrams illustrating application examples of a semiconductor device according to a third embodiment.

### DESCRIPTION OF THE EMBODIMENTS

Some embodiments will be described below with reference to the drawings. The following embodiments do not limit the disclosure according to the claims. While a plurality of features is described in the embodiments, all of the plurality of features are not necessarily essential, and the plurality of features can be optionally combined. In the accompanying drawings, like reference numerals refer to like components, and redundant descriptions will be omitted.

In the following, the embodiments of the present disclosure are described in detail with reference to the drawings. In the following description, terms referring to specific directions and positions (e.g., “up”, “down”, “right”, and “left”, and other terms including these terms) are used as appropriate. These terms are used to facilitate understanding of the embodiments described with reference to the drawings, and the technical scope of the present disclosure is not limited by the meanings of these terms.

In the present specification, plan view refers to viewing in a direction perpendicular to the upper surface of a semiconductor substrate. Further, a cross-section refers to a surface in the direction perpendicular to the upper surface of the semiconductor substrate. In a case where the upper surface of the semiconductor substrate is a rough surface when viewed microscopically, the plan view is defined based on the upper surface of the semiconductor substrate when viewed macroscopically. The upper surface of the semiconductor substrate is defined as a surface on which elements formed on the semiconductor substrate, for example, gates of transistors, or a surface where connection portions with contact plugs are disposed.

Unless otherwise explicitly defined, expressions, such as “A or B”, “at least one of A and B”, “at least one of A and/or B”, and “one or more of A and/or B”, encompass all possible combinations of the listed items. In other words, the above-described expressions are understood to describe all cases including a case where at least one A is included, a case where at least one B is included, and a case where both at least one A and at least one B are included. The same applies to combinations of three or more elements.

### First Embodiment

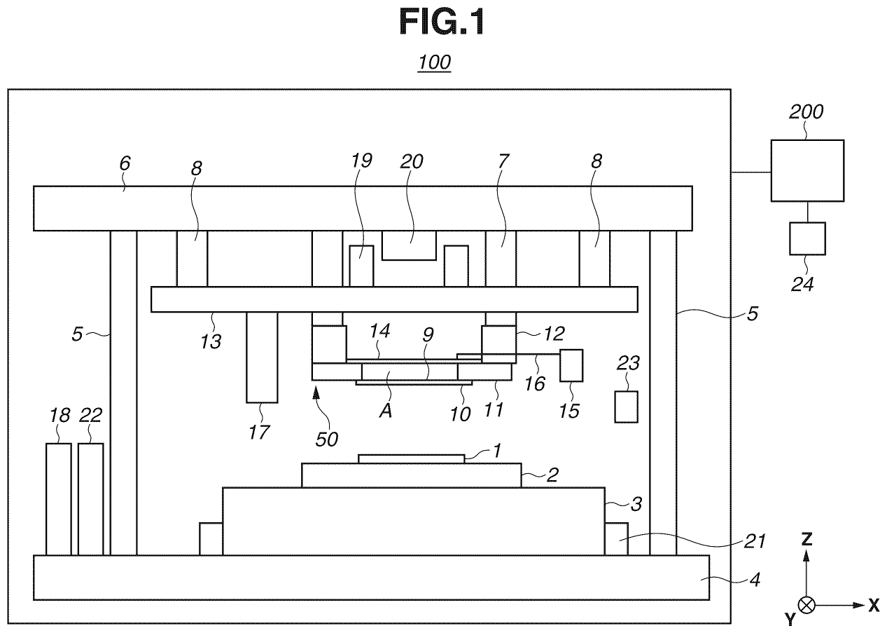

FIG. 1 is a schematic diagram illustrating a configuration of a planarization apparatus 100 according to a first embodiment. Directions are set in an XYZ coordinate system in which an XY plane is a horizontal plane. A substrate 1 as an object to be processed is generally placed on a substrate stage 3 in such a manner that the front surface of the substrate 1 is parallel with the horizontal plane (the XY plane). Thus, in the following, directions orthogonal to each other in a plane along the front surface of the substrate 1 are defined as an X axis and a Y axis, and a direction perpendicular to the X axis and the Y axis is defined as a Z axis. Further, in the following, directions parallel with the X axis, the Y axis, and the Z axis in the XYZ coordinate system are referred to as an X direction, a Y direction, and a Z direction, respectively, and a rotation direction around the X axis, a rotation direction around the Y axis, and a rotation direction around the Z axis are referred to as a θX direction, a θY direction, and a θZ direction, respectively. While the substrate 1 will be described below, the substrate 1 is a member to which a semiconductor process can be applied, and examples of the member include a semiconductor wafer, a semiconductor wafer provided with a wiring structure, a glass substrate provided with elements, and a metal substrate.

An underlying pattern formed on the substrate in a previous step exhibits a surface topology influenced by the pattern. Especially, with the recent advances in multilayer structuring of memory elements, some process substrates may have a step height of approximately 100 nanometers (nm). Step heights caused by moderate undulation of the entire substrate can be corrected by a focus tracking function of a scan exposure apparatus used in a photographing step. However, fine surface topology having a pitch that fits within the exposure slit area of the exposure apparatus may be outside the depth of focus (DOF). Conventionally, as a method of smoothing an underlying pattern of a substrate, a method of forming a planarization layer or performing planarization, such as a spin-on-carbon (SOC) process or a chemical mechanical polishing (CMP) process, respectively, has been used. However, sufficient planarization performance cannot be achieved by the conventional techniques. The manufacturing process has evolved into new technology nodes of, for example, 22 nm, 16 nm, 14 nm, and 10 nm. Even when a planarization layer sufficient for practical use at the node of the previous generation can be produced, the planarization layer may not be adequate for practical use at the node of the subsequent generation. For example, surface topology in the planarization layer that is acceptable at the node of the previous generation cannot be acceptable at the node of the subsequent generation in practice. In addition, while a CMP process is costly in terms of process cost and its applicable steps are limited, the difference in surface topology influenced by an underlying layer through advances in the multilayer structuring tends to be further increased in the future.

To address this issue, a planarization apparatus that performs planarization on a substrate by using an imprint technique is under consideration. The planarization apparatus brings a flat surface of a member or a member without a pattern (a planar template) into contact with a composition in an uncured state previously supplied to a substrate, planarizing a part or the whole of the substrate surface. Thereafter, in a state where the composition and the planar template are in contact with each other, the composition is cured, and the planar template is then separated from the cured composition.

As a result, a planarized layer is formed on the substrate. The planarization apparatus is not affected by a pattern surface topology of a substrate compared with a planarization method using an SOC sacrificial layer generally used, which is expected to increase accuracy of planarization compared with the existing method.

The planarization apparatus 100 illustrated in FIG. 1 can be embodied as a molding apparatus that molds a composition on the substrate 1 by using a plate (a superstrate) 9 serving as a pressing member. The planarization apparatus 100 forms a planarized layer of a material on the substrate 1 by curing a composition in a state where the material on the substrate 1 and the plate 9 are in contact with each other and then separating the plate 9 from the cured composition.

The substrate 1 formed of a semiconductor, an insulator, or a metal may have a circular shape, such as a silicon wafer or a quartz wafer, or a rectangular shape, such as a (mother) glass for a flat panel display (FPD). The material of the substrate 1 may be a single-crystal silicon wafer, but is not limited thereto. The material of the substrate 1 may be a chemical element semiconductor or a compound semiconductor, such as silicon, germanium, diamond, silicon carbide, silicon germanium, gallium nitride, gallium arsenide, indium arsenide, or cadmium telluride. The material of the substrate 1 may be an inorganic insulator, such as silicon oxide, silicon nitride, aluminum oxide, or aluminum nitride. The material of the substrate 1 may be an organic insulator, such as polyimide, polyamide, or polycarbonate. Further, the material of the substrate 1 may be aluminum, a titanium-tungsten alloy, an aluminum-silicon alloy, or an aluminum-copper-silicon alloy. In short, the substrate 1 may be formed of one or a plurality of materials desirably selected from the above-described materials. At least one film formed of a semiconductor, an insulator, or a metal may be provided on the front surface of the substrate 1, and the front surface of the film may be flat or have a surface topology.

Further, an adhesion layer may be formed on the front surface of the substrate 1 by surface treatment, such as silane coupling treatment, silazane treatment, and film formation of a thin organic film, to increase adhesiveness to the composition. The substrate 1 typically has a circular shape having a diameter of 300 millimeters (mm), but is not limited thereto.

The plate 9 may be made of a light-transmissive material in consideration of a light irradiation step. Examples of such a material include a light-transmissive inorganic material, such as glass or quartz, or a light-transmissive organic material, such as polymethyl methacrylate (PMMA) or a polycarbonate resin. The plate 9 may be a plate having rigidity or a flexible film. The plate 9 has a flat surface to come into contact with a composition. It is desirable for the plate 9 to have a circular shape with a diameter greater than 300 mm and smaller than 500 mm, but the shape of the plate 9 is not limited thereto. The thickness of the plate 9 is desirably 0.25 mm or more and less than 2 mm, but is not limited thereto. In a case where the composition is not a photocuring material but a thermosetting material, the plate 9 is not required to be transparent as long as the material has the above-described characteristics.

The composition is a precursor that forms at least a part of the cured planarization film, and is a curable composition that can be cured by receiving light or heat energy. The curable composition that can be cured by receiving light or heat energy may be a photocurable composition that cures by being irradiated with light, a thermosetting composition that cures by heating, or a photo-thermosetting composition that cures by exposure to light and heat energy. Examples of the photocurable composition include ultraviolet (UV) curable liquid. As the UV curable liquid, a monomer, such as acrylate or methacrylate, may be typically used. The curable composition may be referred to as a moldable material. In the following, the moldable material is also simply referred to as “a material”.

As illustrated in FIG. 1, the planarization apparatus 100 includes a substrate chuck 2, the substrate stage 3, a base surface plate 4, columns 5, a top plate 6, a guide bar 7, columns 8, a plate chuck 11, a head 12, and an alignment rack 13. The planarization apparatus 100 further includes a pressure adjustment unit 15, a supplying unit 17, a substrate conveyance unit 18, an alignment scope 19, a light source 20, a stage driving unit 21, a plate conveyance unit 22, a cleaning unit 23, an input unit 24, and a control unit 200. The substrate chuck 2 and the substrate stage 3 can hold and move the substrate 1. The plate chuck 11 and the head 12 can hold and move the plate 9.

The substrate 1 is conveyed from the outside of the planarization apparatus 100 by the substrate conveyance unit 18 including a conveyance hand, and is held by the substrate chuck 2. The substrate stage 3, which is supported by the base surface plate 4, is driven in the X direction and the Y direction in order to position the substrate 1 held by the substrate chuck 2 to a predetermined position. The stage driving unit 21 including, for example, a linear motor and an air cylinder drives the substrate stage 3 at least in the X direction and the Y direction, but may have a function of driving the substrate stage 3 in three or more axis directions (e.g., six axis directions). Further, the stage driving unit 21 may include a rotation mechanism, and rotationally drive the substrate chuck 2 or the substrate stage 3 in the θZ direction.

The plate 9 serving as a pressing member is conveyed from the outside of the planarization apparatus 100 by the plate conveyance unit 22 including a conveyance hand, and is held by the plate chuck 11. The plate 9 having an outer shape that is, for example, circular or rectangular includes a first surface including a flat surface 10 configured to come into contact with a material provided on the substrate 1, and a second surface on the opposite side from the first surface. In the present embodiment, the flat surface 10 has the same size as that of the substrate 1, or has a size greater than that of the substrate 1. The plate chuck 11 is supported by the head 12, and may have a function of correcting the position of the plate 9 in the θZ direction (an inclination around the Z axis). The plate chuck 11 and the head 12 each have an opening that allows light (ultraviolet rays) emitted from the light source 20 through a collimator lens to pass through. The plate chuck 11 functions as a holding unit that mechanically holds the plate 9. For example, the plate chuck 11 attracts the second surface of the plate 9 in a state where the second surface faces upward, to hold the plate 9. The head 12 mechanically holds the plate chuck 11. The plate chuck 11 and the head 12 are included in a formation unit 50 that performs processing of forming a planarization film. The head 12 includes a driving mechanism (not illustrated) for positioning intervals between the substrate 1 and the plate 9 when the plate 9 is brought into contact with the material on the substrate 1 and is separated from the material, and then the head 12 moves the plate 9 in the Z direction. The driving mechanism of the head 12 includes an actuator, such as a linear motor, an air cylinder, and a voice coil motor. Further, a load cell may be disposed on the plate chuck 11 or the head 12 to measure the pressing force of the plate 9 against the material on the substrate 1. A plate deformation mechanism (a plate deformation unit) includes a sealing member 14 that seals a spatial region A formed by a space inside the plate chuck 11 and an internal space surrounded by the plate 9. The plate deformation mechanism further includes the pressure adjustment unit 15 that is installed outside the plate chuck 11 and adjusts pressure inside the spatial region A. The sealing member 14 formed of a light-transmissive plate member, such as quartz glass, has a connection port (not illustrated) for a pipe 16 connected to the pressure adjustment unit 15. The pressure adjustment unit 15 can increase the amount of deformation of the plate 9 so that the plate 9 becomes projected toward the substrate 1 by increasing pressure inside the spatial region A. Further, the pressure adjustment unit 15 can reduce the amount of deformation of the plate 9 into the projected shape by reducing the pressure inside the spatial region A. The columns 5 supporting the top plate 6 are disposed on the base surface plate 4. The guide bar 7 is suspended from the top plate 6, penetrates through the alignment rack 13, and is fixed to the head 12. The alignment rack 13 is suspended from the top plate 6 through the columns 8. The guide bar 7 penetrates through the alignment rack 13. A height measurement system (not illustrated) is disposed on the alignment rack 13 for measuring the height (a flatness) of the substrate 1 held by the substrate chuck 2 by using, for example, an oblique incident image deviation method.

The alignment scope 19 includes an optical system and an imaging system for observing a reference mark provided on the substrate stage 3 and an alignment mark provided on the plate 9. In a case where no alignment mark is provided on the plate 9, the alignment scope 19 may not be included. The alignment scope 19 is used for alignment in which the relative position with respect to the reference mark provided on the substrate stage 3 and the alignment mark provided on the plate 9 is measured, and the positional deviation is corrected.

The supplying unit 17 includes a dispenser including an ejection port (a nozzle) that ejects a material in an uncured state to the substrate 1, and supplies (applies) the material to the substrate 1. The supplying unit 17, which employs, for example, a piezo-jet method or a microsolenoid method, can supply the material having a small volume of about one picoliter (pL) to the substrate 1 while the substrate stage 3 is being driven in a scanning manner. The number of ejection ports of the supplying unit 17 is not limited, and may be one (a single nozzle) or plural (e.g., 100 or more). A single or a plurality of linear nozzle arrays may be formed using a plurality of nozzles. A dispenser of a type known as an inkjet head is particularly suitable because the dispenser can apply a liquid material as minute droplets to the substrate. Especially, a piezo inkjet head that includes at least one ejection energy generator of a piezo element for each ejection port is more suitable because the piezo inkjet head can change the volume of each droplet to be ejected.

The cleaning unit 23 cleans the plate 9 in a state where the plate 9 is held by the plate chuck 11. In the present embodiment, the cleaning unit 23 removes the material adhering to the plate 9, in particular, to the flat surface 10 by separating the plate 9 from the cured material on the substrate 1. For example, the cleaning unit 23 may wipe the material adhering to the plate 9, or may remove the material adhering to the plate 9 by using UV irradiation, static charge removal, wet cleaning, dry plasma cleaning, or the like.

The control unit 200, which includes a computer device including a central processing unit (CPU) and a memory, controls the entire planarization apparatus 100. The control unit 200 functions as a processing unit that generally controls the units of the planarization apparatus 100 to perform planarization processing. The planarization processing refers to processing for planarizing material by bringing the flat surface 10 of the plate 9 into contact with the material on the substrate 1 and then causing the flat surface 10 to conform to the surface shape of the substrate 1. The planarization processing is generally performed on a lot basis, i.e., for each of a plurality of substrates included in the same lot.

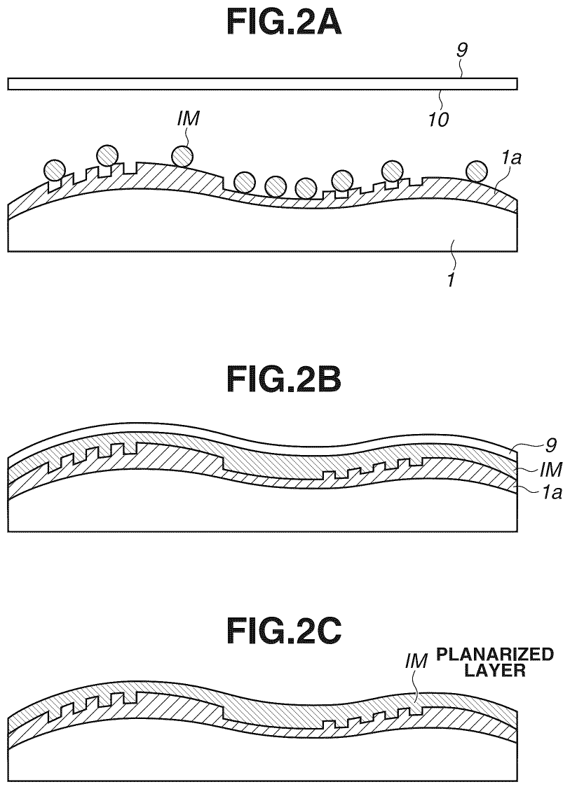

The planarization processing will be described with reference to FIGS. 2A, 2B, and 2C. First, a material IM is supplied from the supplying unit 17 to the substrate 1 having an underlying pattern 1a. FIG. 2A illustrates a state after the material IM is provided on the substrate 1 and before the plate 9 is brought into contact with the material IM. As illustrated in FIG. 2B, the material IM on the substrate 1 and the flat surface 10 of the plate 9 are brought into contact with each other. When the plate 9 presses the material IM, the material IM is spread over the entire surface of the substrate 1. FIG. 2B illustrates a state where the entire flat surface 10 of the plate 9 is in contact with the material IM on the substrate 1, and the flat surface 10 of the plate 9 conforms to the surface shape of the substrate 1. In the state as illustrated in FIG. 2B, the material IM on the substrate 1 is irradiated with light from the light source 20 through the plate 9, which cures the material IM. Thereafter, the plate 9 is separated from the cured material IM on the substrate 1. As a result, a layer (the planarized layer) of the material IM having a uniform thickness is formed on the entire surface of the substrate 1. FIG. 2C illustrates a state where the planarized layer of the material IM is formed on the substrate 1. In the following, contact (adhesion) and separation of the flat surface 10 of the plate 9 and the material IM on the substrate 1 are respectively simply referred to as contact and separation of the plate 9 and the material IM on the substrate 1. Further, in the following, the material IM being supplied to the substrate 1 is also referred to as a precursor, and the cured material IM is also referred to as a film.

A method of manufacturing an item (a semiconductor device, a liquid crystal display device, a color filter, a microelectromechanical system (MEMS), or the like) using the planarization apparatus 100 will now be described. The manufacturing method includes a step of planarizing a composition provided on a substrate (a wafer, a glass substrate, etc.) by bringing the composition and a mold into contact with each other using the above-described planarization apparatus 100, curing the composition, and a step of separating the composition from the mold. A planarization film is formed on the substrate using this method. Further, processing for forming a pattern (patterning) and the like is performed on the substrate provided with the planarization film by using a lithography apparatus, and then the processed substrate is processed by other well-known processes to manufacture an item. The other well-known processes include etching, resist stripping, dicing, bonding, and packaging. According to the manufacturing method, an item having higher quality than that manufactured by the conventional method can be manufactured.

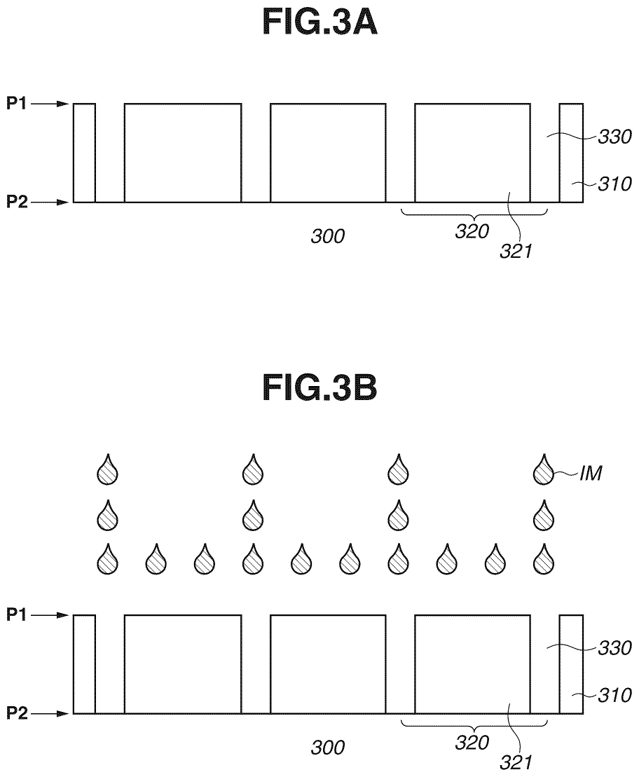

A semiconductor device will now be described as an example of a specific item. The semiconductor device is, for example, a photoelectric conversion sensor. FIGS. 3A and 3B are schematic diagrams illustrating a method for manufacturing a semiconductor device according to the present embodiment.

FIG. 3A illustrates a state where groove portions 330 for isolation portions are formed in a semiconductor substrate 310 by a method, such as photolithography or a Bosch process.

A semiconductor device 300 includes the semiconductor substrate 310, and the semiconductor substrate 310 includes pixels 320. Each of the pixels 320 includes a photoelectric conversion unit 321, and each of the photoelectric conversion units 321 generates electric charge based on incident light. Further, a signal based on the generated electric charge is output from the pixel 320 to column circuits (not illustrated). The column circuits perform various kinds of processing, such as analog-to-digital (AD) conversion processing for converting input signals into digital signals, and processing for reducing noise components. Thereafter, the digital signals are sequentially read from the plurality of column circuits. As a result, the semiconductor device 300 in the present embodiment can generate the signals based on the light entering the photoelectric conversion units 321. A first surface P1 is the upper surface (the light incident surface) of the semiconductor substrate 310, and a second surface P2 is the lower surface of the semiconductor substrate 310, which faces the first surface P1. The semiconductor device 300 is, for example, a backside-illuminated semiconductor device including a plurality of wiring layers (not illustrated) on the side of the second surface P2.

The groove portions 330 each having a trench structure are provided in the first surface P1, and isolate a plurality of semiconductor regions. The photoelectric conversion units 321 are disposed in the plurality of semiconductor regions, and the photoelectric conversion units 321 adjacent to each other are isolated by the corresponding groove portion 330 extending from the first surface P1. In other words, each groove portion 330 is formed between the photoelectric conversion units 321 adjacent to each other in a plan view with respect to the first surface P1. The depth and position of each of the groove portions 330 is not limited to the depth and the position illustrated in FIG. 3A. The groove portions 330 may penetrate through the semiconductor substrate 310, or may not penetrate through the semiconductor substrate 310. The groove portions 330 may be provided to surround the entire periphery of each of the photoelectric conversion units 321 in a plan view, or may be provided, for example, only at opposite sides of each of the photoelectric conversion units 321.

Next, the isolation portions are formed using the groove portions 330. As illustrated in FIG. 3B, after preparing the semiconductor substrate 310 having the groove portions 330 therein, the material IM to serve as a film to be cured is applied. A liquid precursor (the material IM) that is a material to be the isolation portions is applied previously with amounts applied determined so that a large amount of the precursor is applied to upper parts of the groove portions 330 and a small amount of the precursor is applied to other portions. In other words, a greater amount of the precursor is applied to the upper parts of the groove portions 330 than the amount of the precursor applied to upper parts of portions between the plurality of groove portions 330. The amounts applied can be controlled by, for example, changing the number of droplets of the precursor (liquid) as the material IM to be ejected by the inkjet method, or changing the size of liquid droplets. The material IM may be, for example, a precursor of an energy-curable resin or a spin-on-carbon (SOC) precursor.

Uncured material is applied to the upper parts of the groove portions 330 previously formed, by using the inkjet head provided with piezo elements serving as an ejection actuator. Specifically, droplets are applied to the upper parts of the groove portions 330 N times (N is a natural number) per unit area, and droplets are applied to the first surface P1 other than the groove portions 330 N+1 or more times per unit area. The number of droplets to be applied can be determined based on a formation pattern of the groove portions 330. Specifically, droplets are applied while the relative position of the ejection port and the substrate is changed in accordance with a drawing map in which the number (or the amount) of droplets to be applied to the substrate and application positions in the upper surface are determined based on pattern data on a resist mask for formation of the groove portions 330. Depending on the size of droplets, the droplets may enter the insides of the groove portions 330.

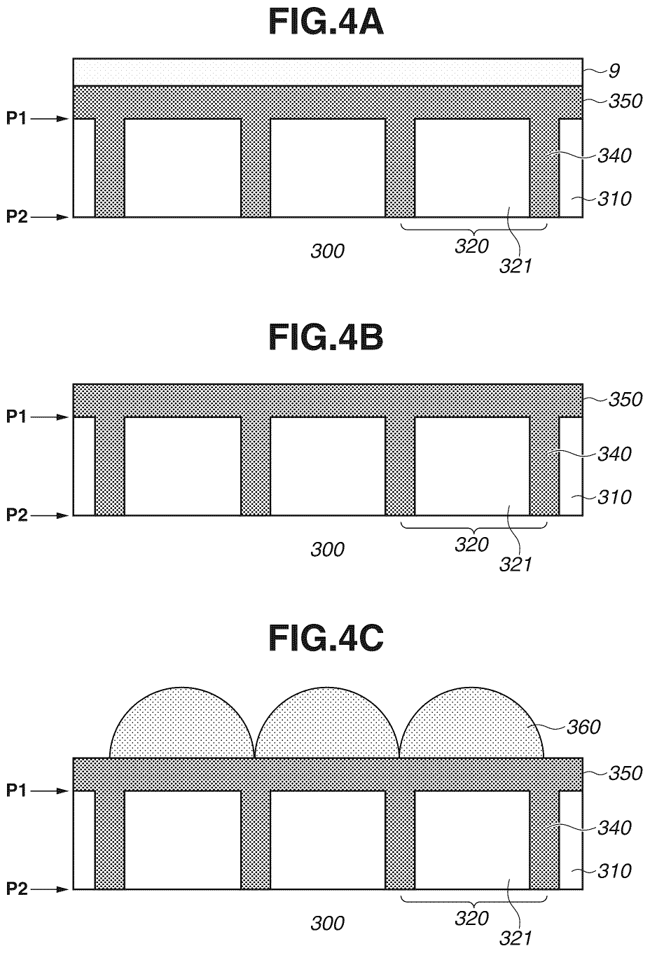

Thereafter, as illustrated in FIG. 4A, the plate 9 is brought into contact with the material IM to planarize the upper surface of the material IM as appropriate. The material IM is then irradiated with light through the plate 9. The material IM is cured by the light being projected on the material IM. For example, an exposure apparatus can be used for curing. The exposure apparatus may be an argon-fluoride (ArF) immersion exposure apparatus, an ArF dry exposure apparatus, or a krypton-fluoride (KrF) exposure apparatus. The amount of exposure may be adjusted based on the pattern of the groove portions 330.

Next, as illustrated in FIG. 4B, the plate 9 is separated from the cured material IM on the semiconductor substrate 310. By the planarization processing, isolation portions 340 inside the groove portions 330, and a first film 350 on the first surface P1 are formed. By using the plate 9 according to the present embodiment, the upper surface of the first film 350 has a high degree of flatness. Further, by using the plate 9 according to the present embodiment, the film thickness of the first film 350 is easily made uniform. The isolation portions 340 may have voids.

Next, as illustrated in FIG. 4C, microlenses 360 may be formed on the upper surface of the first film 350. The microlenses 360 are formed on the first film 350 having a high degree of flatness, and thus, the microlenses 360 easily exert desired performance.

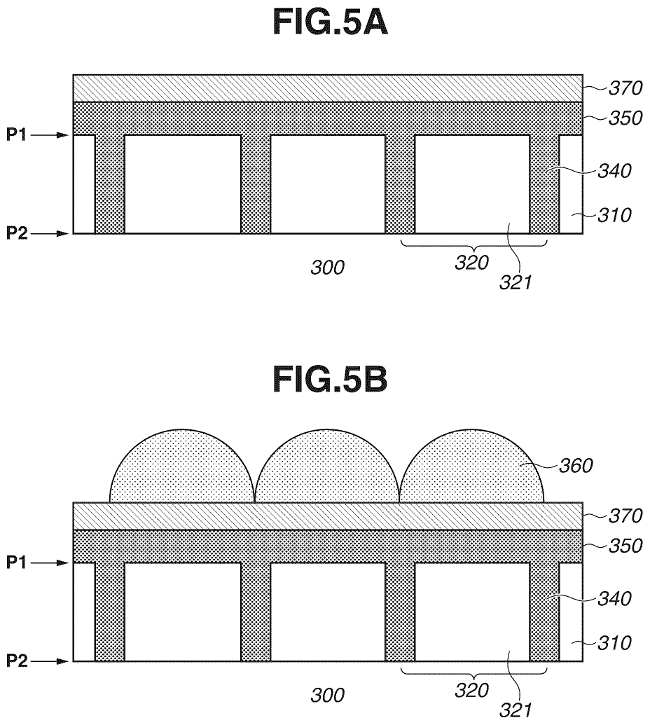

Before the step of forming the microlenses 360 illustrated in FIG. 4C, a filter layer can be formed on the upper surface of the first film 350. FIGS. 5A and 5B illustrate a step of forming the filter layer. As illustrated in FIG. 5A, a filter layer 370 is formed on the upper surface of the first film 350 after the step illustrated in FIG. 4B. Thereafter, as illustrated in FIG. 5B, the microlenses 360 are formed on the upper surface of the filter layer 370. The filter layer 370 is formed on the first film 350 having a high degree of flatness, and thus, the filter layer 370 easily exerts desired performance. For the filter layer 370, various optical filters, such as a color filter, an infrared cut filter, and a monochrome filter, can be used. For the color filter, a red (R), green (G), and blue (B) color filter or a RGBW color filter further including white (W) pixels can be used. W pixels may be provided with an insulating layer in place of the color filter. Another layer may be further provided between the filter layer 370 and the first film 350. Even such a configuration with the first film 350 provided therein can improve flatness as compared with a case where the first film 350 is not provided.

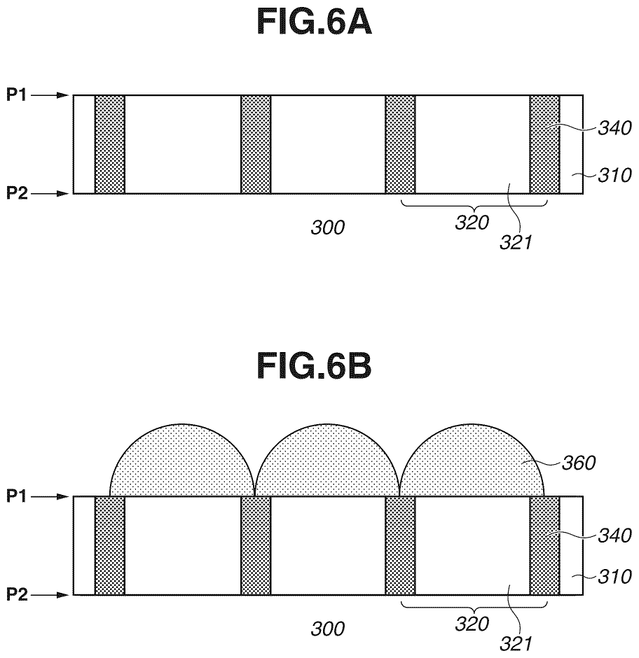

Before the step of forming the microlenses 360 illustrated in FIG. 4C, the first film 350 may be removed. FIGS. 6A and 6B illustrate a step of removing the first film 350. As illustrated in FIG. 6A, the first film 350 is removed after the step illustrated in FIG. 4B. Thereafter, as illustrated in FIG. 6B, the microlenses 360 are formed on the upper surface of the semiconductor substrate 310.

The method described in detail above makes it possible to reduce the number of process steps when the isolation portions are formed. Further, since the planarization processing does not depend on the arrangement density of the isolation portions, a high degree of flatness can be achieved. Consequently, the manufacturing method according to the present embodiment makes it possible to easily form the isolation portions.

In the present embodiment, when the material IM is applied, the inkjet head is configured to be controlled so that the number of droplets to be ejected to the upper parts of the groove portions 330 is greater than the number of droplets to be ejected to the upper parts of portions other than the portions provided with the groove portions 330. However, the ejection form is not limited thereto. For example, when the material IM is applied, the droplets are uniformly applied to the groove portions 330 and the portions other than the portions provided with the groove portions 330. Thereafter, the flat plate 9 is brought into contact with the material IM. Even by the method, the amount of material IM on the upper parts of the groove portions 330 can be set greater than the amount of material IM on the upper parts of the portions other than the portions provided with the groove portions 330. Such a method is also included in the step of applying the precursor so that the amount applied on the upper parts of the groove portions 330 is greater than the amount applied on the portions other than the groove portions 330.

### Second Embodiment

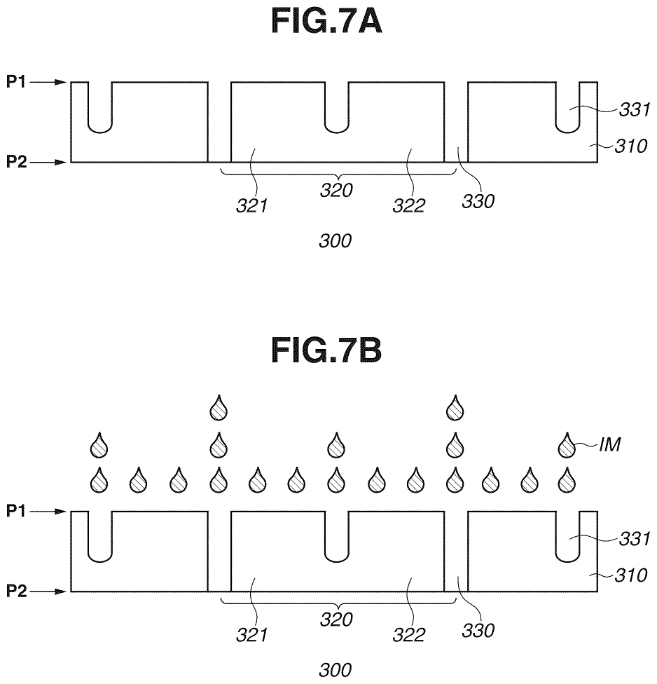

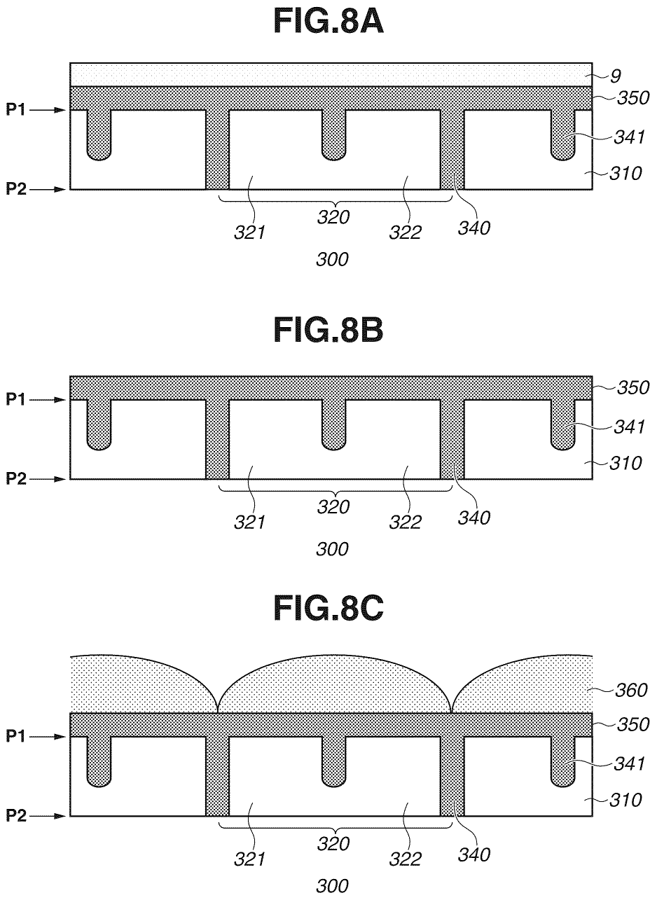

A method will be described for manufacturing a semiconductor device according to a second embodiment. The semiconductor device is, for example, a photoelectric conversion sensor. FIGS. 7A and 7B, and 8A to 8C are schematic diagrams illustrating the method for manufacturing the semiconductor device according to the present embodiment. The manufacturing method illustrated in FIGS. 7A and 7B, and 8A to 8C has a different positional relationship between photoelectric conversion units and microlenses, and different shapes of isolation portions from the manufacturing method described in the first embodiment. In the following, detailed descriptions of configurations and steps similar to the configurations and the steps in the first embodiment will be omitted.

FIG. 7A illustrates a state where groove portions 330 (first portions) and groove portions 331 (second portions) for isolation portions are formed in a semiconductor substrate 310 by a method, such as photolithography or a Bosch process.

Each of the pixels 320 includes a photoelectric conversion unit 321 and a photoelectric conversion unit 322. Each of the photoelectric conversion units 321 and the photoelectric conversion units 322 generates electric charge based on incident light. Focusing adjustment may be performed using signals based on the light entering the photoelectric conversion units 321 and signals based on the light entering the photoelectric conversion units 322.

The groove portions 330 and the groove portions 331 each having a trench structure are provided on the first surface P1. The distance between the bottom part (the lower surface) of each of the groove portions 331 and the second surface P2 is greater than the distance between the bottom part (the lower surface) of each of the groove portions 330 and the second surface P2. The photoelectric conversion unit 321 and the photoelectric conversion unit 322 included in one pixel 320 are separated by the corresponding groove portion 331 extending from the first surface P1. In other words, in a plan view with respect to the first surface P1, each groove portion 331 is formed between the photoelectric conversion unit 321 and the photoelectric conversion unit 322 included in one pixel 320. The photoelectric conversion unit 321 and the photoelectric conversion unit 322 included in different pixel 320 adjacent to each other are isolated by the corresponding groove portion of the groove portions 330. In other words, in a plan view with respect to the first surface P1, each groove portion 330 is provided between a photoelectric conversion unit 321 and a photoelectric conversion unit 322 included in different pixels 320 adjacent to each other. The groove portions 330 may or may not penetrate through the semiconductor substrate 310.

Next, the isolation portions are formed using the groove portions 330 and the groove portions 331. As illustrated in FIG. 7B, after a step of preparing the semiconductor substrate 310 having the groove portions 330 and the groove portions 331, the material IM to serve as a film to be cured is applied. The amount of the material IM applied is adjusted based on the shape of the first surface P1. The liquid precursor (the material IM) that is a material to be the isolation portions is applied previously with the amount applied determined so that a large amount of the precursor is applied to the upper parts of the groove portions 330 and a small amount of precursor is applied to the flat first surface P1 around the upper parts of the groove portions 330. In other words, a greater amount of the precursor is applied to the upper parts of the groove portions 330 than the amount of the precursor applied to upper parts of portions between the plurality of groove portions 330. Further, the liquid precursor (the material IM) that is material to be the isolation portions is applied previously with an application amount determined so that a large amount of the precursor is applied to upper parts of the groove portions 331 and a small amount of the precursor is applied to the flat first surface P1 around the upper parts of the groove portions 331. In other words, a greater amount of the precursor is applied to the upper parts of the groove portions 331 than the amount of the precursor applied to the upper parts of portions among the plurality of groove portions 331. The material IM may be supplied so that the amount of the material IM applied to the upper parts of the groove portions 330 is greater than the amount of the material IM applied to the upper parts of the groove portions 331. The application amount can be controlled by, for example, changing the number of droplets of the precursor (the liquid) of the material IM to be ejected by the inkjet method, or changing the size of each liquid droplet. The material IM may be, for example, a precursor of an energy-curable resin or a spin-on-carbon (SOC) precursor.

Next, as illustrated in FIG. 8A, the plate 9 is brought into contact with the material IM to planarize the upper surface of the material IM, as appropriate. The material IM is then irradiated with light through the plate 9. The material IM is cured by the light being projected on the material IM. For example, an exposure apparatus can be used for curing. The exposure apparatus may be an ArF immersion exposure apparatus, an ArF dry exposure apparatus, or a KrF exposure apparatus. The amount of exposure may be adjusted based on the pattern of the groove portions 330 and the groove portions 331.

Next, as illustrated in FIG. 8B, the plate 9 is separated from the cured material IM on the semiconductor substrate 310. By the planarization processing, isolation portions 340 inside the groove portions 330, isolation portions 341 inside the groove portions 331, and the first film 350 on the first surface P1 are formed. By using the plate 9 according to the present embodiment, the upper surface of the first film 350 has a high degree of flatness. Further, by using the plate 9 according to the present embodiment, the film thickness of the first film 350 is easily made uniform. The isolation portions 340 and the isolation portions 341 may have voids.

Next, as illustrated in FIG. 8C, microlenses 360 may be formed on the upper surface of the first film 350 so as to cover the photoelectric conversion units 321 and the photoelectric conversion units 322 separated by the isolation portions 341. The microlenses 360 are formed on the first film 350 having a high degree of flatness, and thus, easily exert desired performance.

Before the step of forming the microlenses 360 illustrated in FIG. 8C, a filter layer can be formed on the upper surface of the first film 350. The filter layer is formed on the first film 350 having a high degree of flatness, and thus, the filter layer easily exerts desired performance. As the filter layer, various optical filters, such as a color filter, an infrared cut filter, and a monochrome filter can be used. For the color filter, a RGB color filter or a RGBW color filter further including W pixels can be used. W pixels may be provided with an insulating layer in place of the color filter. In this case, the colors of the filter layer corresponding to the photoelectric conversion units 321 and the photoelectric conversion units 322 separated by the isolation portions 341 can be the same.

Before the step of forming the microlenses 360 illustrated in FIG. 8C, the first film 350 may be removed.

The method described in detail above makes it possible to reduce the number of process steps when the isolation portions are formed. Further, since the planarization processing does not depend on the arrangement density of the isolation portions, a high degree of flatness can be achieved. The manufacturing method according to the present embodiment makes it possible to easily form the isolation portions.

In the present embodiment, when the material IM is applied, the inkjet head is configured to be controlled so that the number of droplets to be ejected to the upper parts of the groove portions 330 is greater than the number of droplets to be ejected to the upper parts of portions other than the portions provided with the groove portions 330. However, the ejection form is not limited thereto. For example, when the material IM is applied, the droplets are uniformly applied to the groove portions 330 and the portions other than the portions provided with the groove portions 330. Thereafter, the flat plate 9 is brought into contact with the material IM. Even by the method, the amount of material IM on the upper parts of the groove portions 330 can be set greater than the amount of material IM on the upper parts of the portions other than the portions provided with the groove portions 330. Such a method is also included in the step of applying the precursor so that the amount applied on the upper parts of the groove portions 330 is greater than the amount applied on the portions other than the groove portions 330.

In the present embodiment, when the material IM is applied, the inkjet head is configured so that the number of droplets to be ejected to the upper parts of the groove portions 331 is greater than the number of droplets to be ejected to the upper parts of portions other than the portions provided with the groove portions 331. However, the ejection form is not limited thereto. For example, when the material IM is applied, the droplets are uniformly applied to the groove portions 331 and the portions other than the portions provided with the groove portions 331. Thereafter, the flat plate 9 is brought into contact with the material IM. Even by the method, the amount of material IM on the upper parts of the groove portions 331 can be set greater than the amount of material IM on the upper parts of the portions other than the portions provided with the groove portions 331. Such a method is also included in the step of applying the precursor so that the amount applied on the upper parts of the groove portions 331 is greater than the amount applied on the portions other than the groove portions 331.

### Third Embodiment

In a third embodiment, application examples using the semiconductor device manufactured by the manufacturing method according to the first embodiment or the second embodiment will be described. A semiconductor device 910 is, for example, a photoelectric conversion sensor.

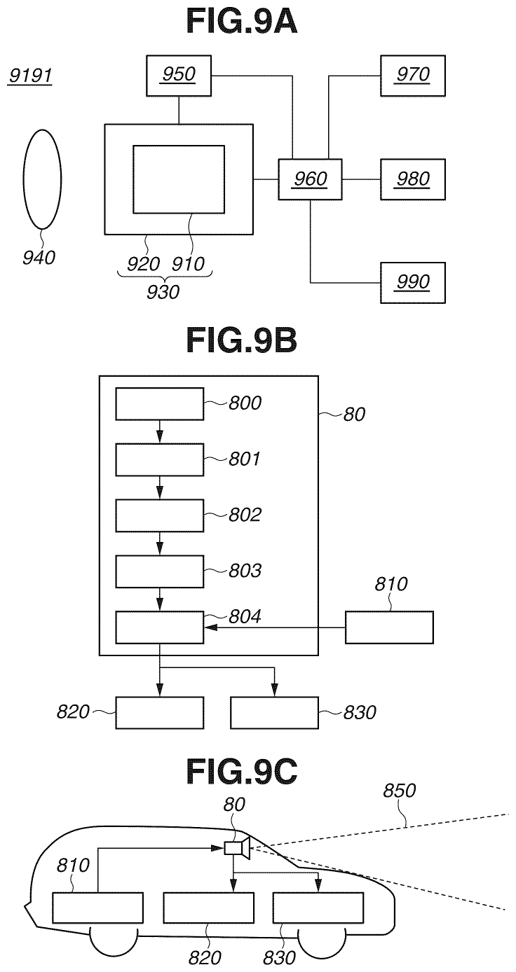

FIG. 9A is a schematic diagram illustrating an apparatus 9191 according to an application example. The apparatus 9191 includes a semiconductor apparatus 930. The semiconductor apparatus 930 includes the semiconductor device 910, and a package 920 for housing the semiconductor device 910. The semiconductor device 910 can be manufactured by a manufacturing method according to another embodiment. The package 920 can include a base to which the semiconductor device 910 is fixed, and a lid made of, for example, glass, facing the semiconductor device 910. The package 920 can further include joining members, such as bonding wires or bumps, for connecting a terminal provided on the base and a terminal provided on the semiconductor device 910.

The apparatus 9191 can include at least any of an optical device 940, a control device 950, a processing device 960, a display device 970, a storage device 980, and a mechanical device 990. The optical device 940 is used for the semiconductor apparatus 930. The optical device 940 is, for example, a lens, a shutter, or a mirror as an optical system that guides light to the semiconductor apparatus 930. The control device 950 controls the semiconductor apparatus 930. The control device 950 is a semiconductor device, such as an Application Specific Integrated Circuit (ASIC).

The processing device 960 processes signals output from the semiconductor apparatus 930. The processing device 960 is a semiconductor device, such as a central processing unit (CPU) and an ASIC for configuring an analog front end (AFE) or a digital front end (DFE). The display device 970 is an electroluminescence (EL) display device or a liquid crystal display device that displays information (images) acquired by the semiconductor apparatus 930. The storage device 980 is a magnetic device or a semiconductor device that stores the information (the images) acquired by the semiconductor apparatus 930. The storage device 980 is a volatile memory, such as a static random-access memory (SRAM) and a dynamic random-access memory (DRAM), or a nonvolatile memory, such as a flash memory and a hard disk drive.

The mechanical device 990 includes a moving unit or a propulsion unit, such as a motor or an engine. In the apparatus 9191, signals output from the semiconductor apparatus 930 are displayed on the display device 970, and are transmitted to the outside via a communication device (not illustrated) included in the apparatus 9191. Thus, the apparatus 9191 can further include the storage device 980 and the processing device 960 in addition to a storage circuit and a calculation circuit included in the semiconductor apparatus 930. The mechanical device 990 can be controlled based on signals output from the semiconductor apparatus 930.

The apparatus 9191 is suitable for an electronic device, such as an information terminal having an imaging function (e.g., a smartphone and a wearable terminal), and a camera (e.g., an interchangeable-lens camera, a compact camera, a video camera, and a monitoring camera). The mechanical device 990 in the camera can drive parts of the optical device 940 in order to perform zooming, focusing, and shutter operation. Alternatively, the mechanical device 990 in the camera can move the semiconductor apparatus 930 for anti-shake operation.

The apparatus 9191 may be a transport device, such as a vehicle, a vessel, or an aircraft. The mechanical device 990 in the transport device can be used as a moving device. The apparatus 9191 serving as the transport apparatus is suitable for transporting the semiconductor apparatus 930, or assisting and/or automating operation (steering) through an imaging function. The processing device 960 for assisting and/or automating operation (steering) can perform processing for operating the mechanical device 990 serving as a moving device based on the information acquired by the semiconductor apparatus 930. Alternatively, the apparatus 9191 may be a medical device, such as an endoscope, a measuring instrument, such as a distance sensor, an analytical instrument, such as an electron microscope, an office device, such as a copier, or an industrial device, such as a robot.

According to the above-described embodiments, good pixel characteristics can be achieved. This makes it possible to enhance the value of the semiconductor device. Enhancement of the value refers to at least any of addition of a function, increase in performance, improvement of characteristics, increase in reliability, improvement of a manufacturing yield, reduction of environmental impact, cost reduction, downsizing, and weight reduction.

Thus, the use of the semiconductor apparatus 930 according to the present embodiment in the apparatus 9191 also makes it possible to increase the value of the apparatus. For example, the semiconductor apparatus 930 mounted on a transport device makes it possible to provide good performance during imaging of the outside of the transport apparatus or measurement of the external environment being performed. Thus, in a case where the transport device is manufactured and sold, determining to mount the semiconductor device according to the present embodiment on the transport device is advantageous for enhancing performance of the transport device itself. Especially, the semiconductor apparatus 930 is suitable for a transport device that performs operation assist and/or automatic operation by using information acquired by the semiconductor apparatus 930.

A mobile body will now be described as another application example. FIG. 9B illustrates an example of a photoelectric conversion system relating to an in-vehicle camera. A photoelectric conversion system 80 includes a semiconductor device 800. The semiconductor device 800 is, for example, a photoelectric conversion device (an imaging device). The photoelectric conversion system 80 includes an image processing unit 801 and a parallax acquisition unit 802. The image processing unit 801 performs image processing on a plurality of pieces of image data acquired by the semiconductor device 800. The parallax acquisition unit 802 calculates parallax (phase difference of parallax images) from the plurality of pieces of image data acquired by the photoelectric conversion system 80.

The photoelectric conversion system 80 may include an optical system (not illustrated) that guides light to the semiconductor device 800, such as a lens, a shutter, and a mirror. Further, a plurality of photoelectric conversion units substantially conjugate to a pupil of the optical system may be arranged in a pixel of the semiconductor device 800. For example, the plurality of photoelectric conversion units substantially conjugate to the pupil is arranged corresponding to one microlens. The plurality of photoelectric conversion units receives light fluxes that have passed through mutually different points on the pupil of the optical system, and the semiconductor device 800 outputs pieces of image data corresponding to the light fluxes that have passed through the different points. Thereafter, the parallax acquisition unit 802 may calculate parallax by using the output pieces of image data. Further, the photoelectric conversion system 80 includes a distance acquisition unit 803 and a collision determination unit 804. The distance acquisition unit 803 calculates a distance to an object based on the calculated parallax. The collision determination unit 804 determines whether there is a collision likelihood based on the calculated distance. The parallax acquisition unit 802 and the distance acquisition unit 803 are each an example of a distance information acquisition unit that acquire distance information to the object. In other words, the distance information includes information about parallax, an amount of defocus, and a distance to the object. The collision determination unit 804 may determine the collision likelihood by using any of the pieces of information included in the distance information. The distance information may be acquired by a time-of-flight (ToF) method. The distance information acquisition unit may be implemented by dedicatedly designed hardware, or may be implemented by a software module. The distance information acquisition unit may be implemented by a field programmable gate array (FPGA), an ASIC, or the like, or may be implemented by a combination thereof.

The photoelectric conversion system 80, which is connected to a vehicle information acquisition device 810, can acquire vehicle information, such as a vehicle speed, a yaw rate, and a steering angle. Further, the photoelectric conversion system 80 is connected to a control electric control unit (ECU) 820 as a control device that outputs a control signal for causing a vehicle to generate braking force based on a determination result of the collision determination unit 804. The photoelectric conversion system 80 is also connected to an alarm device 830 that issues an alarm to a driver based on a determination result of the collision determination unit 804. For example, in a case where the collision likelihood is high as a determination result of the collision determination unit 804, the control ECU 820 performs vehicle control to avoid collision or reduce damage by applying a brake, releasing the accelerator, reducing engine output, and the like. The alarm device 830 warns a user by sounding an alarm, such as sound, displaying warning information on a screen of a car navigation system or the like, and vibrating a seat belt and a steering wheel, or the like.

In the present embodiment, the surroundings of the vehicle, for example, a region in front of or behind the vehicle, are imaged by the photoelectric conversion system 80. FIG. 9C illustrates the photoelectric conversion system 80 in a case where a region (an imaging range 850) in front of the vehicle is imaged. The vehicle information acquisition unit 810 transmits an instruction to the photoelectric conversion system 80 or the semiconductor device 800. This configuration makes it possible to further increase accuracy of distance measurement.

While the example is described of control to avoid collision with another vehicle, the present embodiment is applicable to control for automatic driving that follows another vehicle, control for automatic driving that prevents deviation from a traffic lane, and the like. The photoelectric conversion system 80 can be applied to a vehicle, such as an automobile, as well as to a mobile body (a mobile apparatus), such as a vessel, an aircraft, and an industrial robot. The mobile body includes either or both a driving force generation unit that generates driving force mainly used for movement of the mobile body, or/and a rotating body that is mainly used for movement of the mobile body. The driving force generation unit can be an engine, a motor, or the like. The rotating body can be a tire, a wheel, a screw of a vessel, a propeller, or the like. In addition, the present embodiment can be widely applied to apparatuses that use object recognition, such as Intelligent Transport Systems (ITS), without being limited to the mobile body.

The apparatus according to the present embodiment can be a transport device, such as a vehicle, a vessel, and a flight body. The mechanical device in the transport device can be used as a mobile apparatus. The device serving as the transport device is suitable for transporting the semiconductor device, or assisting and/or automating operation (steering) through an imaging function. The processing device for assisting and/or automating operation (steering) can perform processing for operating the mechanical device serving as a mobile apparatus based on information acquired by the semiconductor device.

In the present embodiment, the photoelectric conversion device is described as an example of the semiconductor device, but the semiconductor device can be another semiconductor device, or both the photoelectric conversion device and another semiconductor device.

According to the embodiments of the present disclosure, isolation portions can be easily formed.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-230271, filed Dec. 26, 2024, which is hereby incorporated by reference herein in its entirety.

What is claimed is:

1. A method for manufacturing a semiconductor device including a substrate, the substrate including a first surface, a second surface opposed to the first surface, and a plurality of semiconductor regions disposed between the first surface and the second surface, the method comprising:
preparing the substrate having groove portions disposed between the plurality of semiconductor regions, each of the groove portions having a trench structure extending from the first surface; and
forming a first film having a flat upper surface on the substrate by applying a precursor so that an amount of the precursor applied on upper parts of the groove portions is greater than an amount of the precursor applied on portions other than the upper parts of the groove portions.

2. The method for manufacturing the semiconductor device according to claim 1, wherein the forming the first film includes planarizing an upper surface of the precursor and curing the precursor to have the flat upper surface.

3. The method for manufacturing the semiconductor device according to claim 1, wherein the forming the first film includes bringing a superstrate into contact with the precursor.

4. The method for manufacturing the semiconductor device according to claim 3, wherein in the forming the first film, the precursor is cured in a state where the superstrate is in contact with the precursor.

5. The method for manufacturing the semiconductor device according to claim 1,
wherein the substrate includes a photoelectric conversion unit configured to generate electric charge based on light entering from the first surface, and
wherein in a plan view with respect to the first surface, the photoelectric conversion unit is disposed between a part of the groove portions and another part of the groove portions.

6. The method for manufacturing the semiconductor device according to claim 5, wherein in the forming the first film, the precursor is applied so that an amount of the precursor applied to an upper part of the photoelectric conversion unit is less than the amount of the precursor applied to the upper parts of the groove portions.

7. The method for manufacturing the semiconductor device according to claim 1,
wherein the groove portions include first portions and second portions, and
wherein in the forming the first film, the precursor is applied so that an amount of the precursor applied to upper parts of the first portions is less than an amount of the precursor applied to upper parts of the second portions.

8. The method for manufacturing the semiconductor device according to claim 7, wherein a distance between a bottom part of each of the first portions and the second surface is greater than a distance between a bottom part of each of the second portions and the second surface.

9. The method for manufacturing the semiconductor device according to claim 8, further comprising forming microlenses on the first film,
wherein in the forming the microlenses, one microlens is formed to cover the plurality of semiconductor regions separated by each of the first portions.

10. The method for manufacturing the semiconductor device according to claim 1,
wherein the semiconductor device includes a plurality of wiring layers, and
wherein the second surface is disposed between the first surface and the plurality of wiring layers.

11. The method for manufacturing the semiconductor device according to claim 1, further comprising forming microlenses on the first film.

12. The method for manufacturing the semiconductor device according to claim 1, further comprising forming a filter layer on the first film.

13. The method for manufacturing the semiconductor device according to claim 1, further comprising:
forming a filter layer on the first film; and
forming microlenses on the filter layer.
